(19) United States
(12) Patent Application Publication
(10) Pub. No.: US 2024/0055269 A1
(43) Pub. Date: Feb. 15, 2024

(54) DRY ETCH FOR NITRIDE EXHUME PROCESSES IN 3D NAND FABRICATION

(71) Applicant: Applied Materials, Inc., Santa Clara, CA (US)

(72) Inventors: Sankuei Lin, Los Gatos, CA (US); Changwoo Sun, Ontario (CA); Pradeep K. Subrahmanyan, San Jose, CA (US)

(73) Assignee: Applied Materials, Inc., Santa Clara, CA (US)

(21) Appl. No.: 17/886,285

(22) Filed: Aug. 11, 2022

(51) Int. Cl. H01L 21/311; H01L 27/115

(52) U.S. Cl. CPC H01L 21/31116; H01L 27/115; H01L 21/31144

(57) ABSTRACT

A three-dimensional (3D) NAND memory structure may include alternating layers of materials arranged in a vertical stack on a silicon substrate, such as alternating oxide and nitride layers. The alternating nitride layers may later be removed, and the recesses may be filled with a conductive material to form word lines for the memory array. To avoid pinching off these recesses with silicon byproducts from a traditional wet etch, a dry etch may be instead be used to remove the nitrite layers. To protect the silicon substrate, a first insulating layer may be deposited at the bottom of the slit to cover the exposed silicon substrate before performing the dry etch. After applying a second insulating layer to cover the alternating oxide/nitride layers, a directional etch may punch through both insulating layers to again expose the silicon substrate before applying a solid material fill in the slit.

### TECHNICAL FIELD

This disclosure generally describes three-dimensional (3D) NAND memory. More specifically, this disclosure describes structures and techniques for fabricating 3D NAND memory structures by exhuming alternating nitride layers that are replaced with conductive layers using a dry etch, during which an underlying silicon substrate may be protected by an insulating layer.

### BACKGROUND

A memory design known as NAND memory is a non-volatile flash memory storage architecture that does not require power to maintain its stored data. NAND flash memory is used in many products, such as solid-state devices and portable electronics. In order to improve the density and reduce the size of NAND memories, traditional two-dimensional NAND architectures have transitioned to three-dimensional NAND stacks. Unlike 2D planar NAND technologies where the individual memory cells are stacked together on separate horizontal substrates, 3D NAND is stacked vertically using multiple layers of alternating conducting and dielectric materials with intersecting vertical channels.

### SUMMARY

In some embodiments, a three-dimensional (3D) NAND memory structure may include a silicon substrate and a plurality of alternating material layers that may be arranged in a vertical stack on the silicon substrate. A slit may extend through the plurality of alternating material layers to the silicon substrate to divide a plurality of channel holes into a memory array. The slit may be perpendicular to the plurality of alternating material layers. The 3D NAND memory structure may also include a first insulating layer deposited at the bottom of the slit. The first insulating layer may include a material that protects the silicon substrate during a dry etch process that may selectively remove first alternating material layers from the plurality of alternating material layers.

In some embodiments, a 3D NAND memory structure may include a silicon substrate and a plurality of alternating material layers that may be arranged in a vertical stack on the silicon substrate. A slit may extend through the plurality of alternating material layers to the silicon substrate to divide a plurality of channel holes in a memory array. The slit may be perpendicular to the plurality of alternating material layers. The 3D NAND memory structure may also include a first insulating layer coating sides of a bottom portion of the slit, and a second insulating layer coating sides of a top portion of the slit.

In some embodiments, a method of fabricating a 3D NAND memory structure may include forming a plurality of alternating material layers arranged in a vertical stack on a silicon substrate; etching a slit that extends through the plurality of alternating material layers to the silicon substrate; depositing a first insulating layer at the bottom of the slit; and performing a dry etch to selectively remove first alternating material layers from the plurality of alternating material layers in the vertical stack. The first insulating layer may include a material that protects the silicon substrate during the dry etch process.

In any embodiments, any and all of the following features may be implemented in any combination and without limitation. The alternating material layers may include alternating layers of an oxide material and a nitride material. A first material layer in the plurality of alternating material layers that may be adjacent to the silicon substrate may be thicker than the remaining material layers in the plurality of alternating material layers. The slit may extend to a surface of the silicon substrate without penetrating the surface of the silicon substrate. The slit ma extend below a surface of the silicon substrate. The first insulating layer may extend below a surface of the silicon substrate. A top of the first insulating layer may be between a surface of the silicon substrate and a top of a first material layer in the plurality of alternating material layers that may be adjacent to the silicon substrate. The first insulating layer may not coat sides of the slit above the top of the first insulating layer. The alternating material layers may include alternating layers of an oxide material and a metal, where the metal may form a gate electrode for individual memory cells in the memory structure. The first insulating layer may include a silicon oxide material. A top of the first insulating layer may be between a surface of the silicon substrate and a top of a first material layer in the plurality of alternating material layers that may be adjacent to the silicon substrate. The 3D NAND memory structure may also include a solid fill material inside the first insulating layer and the second insulating layer. The dry etch process may use gases that may also selectively remove a portion of the silicon substrate if not protected by the first insulating layer. For example, the gases may include NF3 and O2, NF3 and H2, or ClF3 and H2. The method/operations may also include filling recesses left after removing the first alternating material layers with a conductive material to form word lines for the memory structure. The method/operations may also include depositing a second insulating layer on top of the first insulating layer such that the second insulating layer coats a top of the first insulating layer and coats sides of the slit. The method/operations may also include etching a hole through the second insulating layer that coats the top of the first insulating layer and the second insulating layer to expose the silicon substrate using a directional etch to leave the second insulating layer that coats the sides of the slit. The method/operations may also include filling the hole with a solid fill material.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of one embodiment of a processing system of deposition, etching, baking, and curing chambers according to some embodiments.

FIGS. 2A-2C illustrates steps for removing nitride layers from a 3D NAND memory structure using a wet etch, according to some embodiments.

FIGS. 3A-31I illustrate process steps for forming a 3D NAND memory structure using a protective insulating layer and a dry etch process for exhuming the nitride layers, according to some embodiments.

FIG. 4 illustrates a flowchart of a method for fabricating a 3D NAND memory structure, according to some embodiments.

### DETAILED DESCRIPTION

A three-dimensional (3D) NAND memory structure may include alternating layers of materials arranged in a vertical stack on a silicon substrate, such as alternating oxide and nitride layers. The alternating nitride layers may later be removed, and the recesses may be filled with a conductive material to form word lines for the memory array. To avoid pinching off these recesses with silicon byproducts from a traditional wet etch, a dry etch may be instead be used to remove the nitrite layers. To protect the silicon substrate, a first insulating layer may be deposited at the bottom of the slit to cover the exposed silicon substrate before performing the dry etch. After applying a second insulating layer to cover the alternating oxide/nitride layers, a directional etch may punch through both insulating layers to again expose the silicon substrate before applying a solid material fill in the slit.

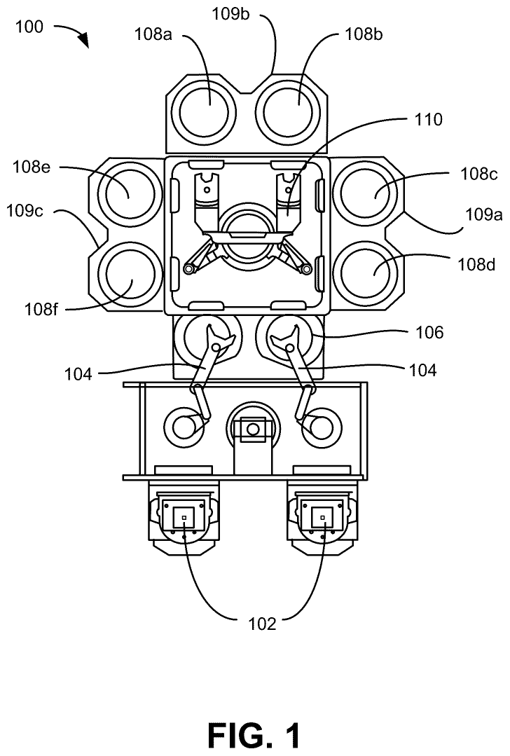

FIG. 1 illustrates a top plan view of one embodiment of a processing system 100 of deposition, etching, baking, and curing chambers according to some embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by the processing system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

The processing system 100, or more specifically chambers incorporated into the processing system 100 or other processing systems, may be used to produce structures according to some embodiments of the present technology. For example, the processing system 100 may be used to produce memory arrays by performing operations such as deposition, etch, sputtering, polishing, cleaning, and so forth, in the various substrate processing chambers 108. Each of these operations may be separately controlled by a recipe or by a group of recipes that control the environmental conditions and/or steps performed by the various processing chambers 108. For example, a computer system or controller may include a non-transitory computer-readable medium that stores instructions that embody the recipe performed. These instructions may control the loading/unloading of substrates into the processing chambers 108, as well as the various operations performed inside the processing chambers 108. For example, each of the methods described below may be represented as a recipe or as a set of instructions that is executed by one or more processors. Each of the following methods may also be stored on one or more memory devices as instructions representing one or more recipes performed by the processing chambers 108.

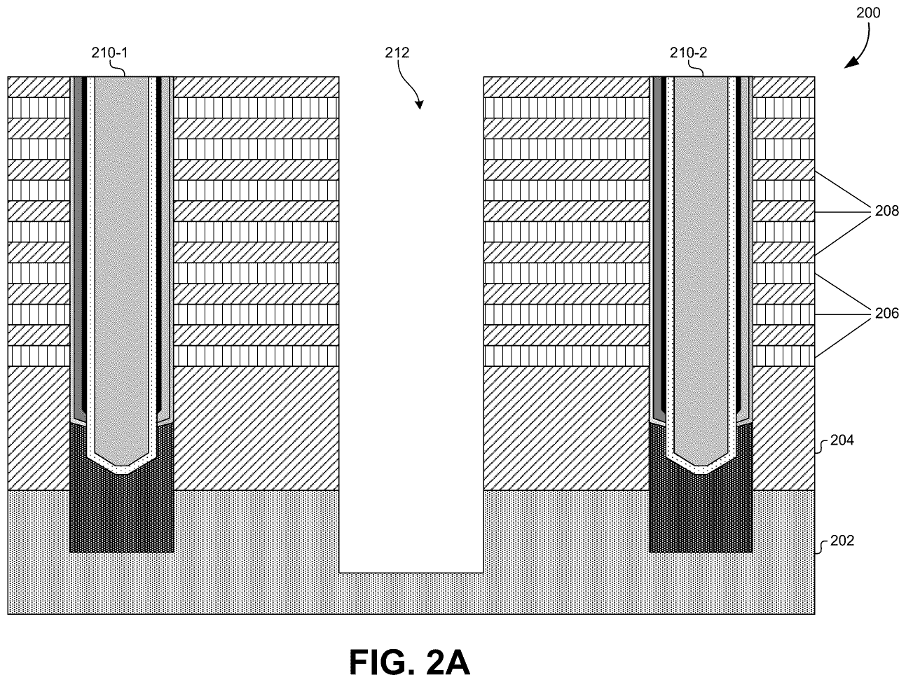

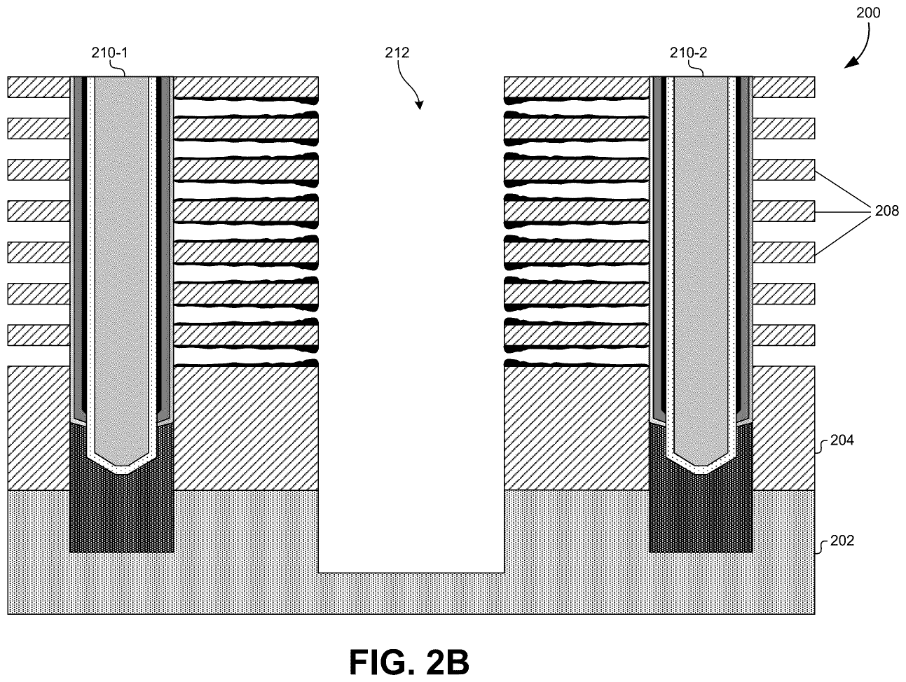

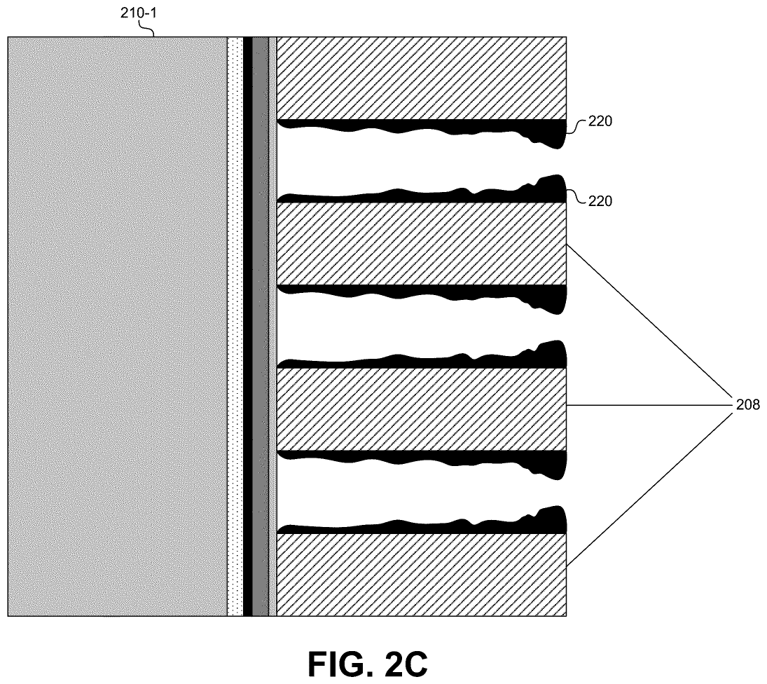

FIGS. 2A-2C illustrates steps for removing nitride layers from a 3D NAND memory structure 200 using a wet etch, according to some embodiments. These figures illustrate the incremental stages for generating an array of 3D NAND flash memory cells. FIG. 2A illustrates a stack of alternating nitride layers 206 and oxide layers 208 that may be formed for the 3D NAND flash array. Each of the layers 206, 208 illustrated in FIG. 2A may be formed incrementally, one layer on top of the previous layer using any deposition or layer formation techniques. In this example, the layers may be formed on a silicon substrate 202 of a silicon material, such as polysilicon, epitaxial silicon, single-crystal silicon, and/or any other type of substrate.

The alternating oxide layers 206 and nitride layers 208 may be collectively referred to as a plurality of alternating material layers that are arranged in a vertical stack on the silicon substrate 202. In this example, the nitride layers 206 may include a first material, such as silicon nitride, and may be collectively referred to as first alternating material layers in the plurality of alternating material layers. Similarly, the oxide layers 208 may include a second material, such as silicon dioxide, and may be collectively referred to as second alternating material layers in the plurality of alternating material layers. Note that silicon nitride and silicon dioxide are provided only by way of example, and are not meant to be limiting. Other materials may be used that exhibit similar characteristics. Furthermore, these layers may be removed and replaced with other layers later in the fabrication process, such as being replaced by conductive metal layers as described below.

In some embodiments, a first material layer 204 may represent a first oxide layer deposited on top of or adjacent to the silicon substrate 202. The first material layer 204 may be formed from silicon dioxide or any other type of oxide. In some embodiments, the first material layer 204 may be thicker than the other oxide layers 208 in the 3D NAND memory structure 200. For example, the first material layer 204 may be at least twice as thick, three times as thick, four times as thick, five times as thick, 10 times as thick, 15 times as thick, 20 times as thick, as the other oxide layers 208. In some implementations, the first material layer 204 may be between two times as thick and four times as thick as the other oxide layers 208, between four times as thick and six times as thick, between six times as thick and eight times as thick, between eight times as thick and 10 times as thick, between 10 times as thick and 15 times as thick, between 15 times as thick and 20 times as thick, and so forth, depending on the specific circuit design.

As part of the 3D NAND memory structure 200, a plurality of channel holes 210 may be etched and formed in the 3D NAND memory structure 200 to form vertical arrays of memory elements. These channel holes may be lined with a tunneling layer and a layer of silicon to form the channels of the storage elements of the memory devices. The channel holes 210 may be filled using polysilicon or an oxide core. Although the 3D NAND memory structure 200 depicted in FIG. 2A only illustrates two channel holes 210-1, 210-2, it should be understood that many additional channel holes may be present in the 3D NAND memory structure 200. For example, additional channel holes may extend to the left or the right of FIG. 2A out the visible range of the figure. Furthermore, more channel holes may be present in front of or behind the channel holes 210, which are not visible in the cross-sectional view of FIG. 2A.

The 3D NAND memory structure 200 may also include one or more slits. The slits may be etched through the plurality of alternating material layers down to the silicon substrate 202. The slits may be filled with an insulator material, such as an oxide or left vacant. One purpose of the slits may be to separate or divide the word lines in each layer that surround the channel holes 210 in to form sections or words in the memory array. Additionally, the slits may provide access to the alternating layers of material in order to remove some layers and replace them with conductive materials as described below.

FIG. 2A illustrates a slit 212 that has been etched through the plurality of alternating materials down through to the silicon substrate 202. In this example, the slit 212 extends down into the silicon substrate 202, penetrating below a top surface of the silicon substrate 202. However, in other embodiments the slit 212 may extend down to the surface of the silicon substrate 202 without necessarily penetrating the top surface of the silicon substrate 202. The slit 212 may extend through the vertical stack to be adjacent to a plurality of channel holes on either side of the slit 212, which may not be visible in the cross-sectional view of FIG. 2A. In addition to separating the channel hole 210-1 from the channel hole 210-2 into separate portions of the memory array, the slit 212 may also be used to provide access to the alternating nitride layers 206 in order to remove the nitride layers 206 during the fabrication process.

FIG. 2B illustrates a nitride removal process using a wet etch, according to some embodiments. In order to remove the nitride layers 206, access may be provided to the nitride layers 206 through the slit 212. The nitride layers 206 may be sacrificial layers that are used to build up the plurality of alternating material layers during the first stages of fabricating the 3D NAND memory structure 200. The nitride layers 206 may be removed once the channel holes 210 and other features have been formed. After removal, the nitride layers 206 may leave behind recesses that can be filled with a conductive material, such as tungsten to provide a conductive word lines for the memory array.

In some processes, the nitride layers 206 may be removed using a wet etch. For example, a wet etch may be executed by applying a wet etchant, such as phosphoric acid, to the 3D NAND memory structure 200. The phosphoric acid is able to remove the nitride layers 206 from the slit 212. A wet etch is typically used because it is very selective to the nitride layers 206. Specifically, the phosphoric acid does not remove a significant amount of material from either the exposed silicon substrate 202 at the bottom of the slit 212 or the oxide layers 208, while still effectively removing the nitride layers.

However, it is been discovered that the wet etch process also presents some technical problems that complicate the formation of the metal word lines between the remaining oxide layers 208. Specifically, as the nitride material is dissolved in the wet etch bath, nonhomogeneous silicate byproducts may build up in the solution. As the etch process proceeds, the concentration of the silicate byproducts may continue to build up in the solution over time. When the concentration reaches a certain level, the silicate byproducts may begin to solidify and build up on the surface of the oxide layers 208. This buildup may “pinch off” the horizontal trenches or recesses between the oxide layers 208.

FIG. 2C illustrates a magnified view of the recesses left after removing the first alternating material layers of nitride using a wet etch process, according to some embodiments. As illustrated in this figure, the silicate byproducts 220 begin to build up in the recesses left behind during the etch process. In some cases, the silicate byproducts 220 tend to build up the most at the entrance of the recesses, although the silicate byproducts 220 may also extend throughout the length of the recesses. The silicate byproducts 220 may be problematic when the recesses are later filled with a conductive material to form the word lines by providing less room for the metal fill. As a result, the metal word lines may not be uniformly thick throughout their length and may include areas that are significantly thinner due to the silicate byproducts 220. As the word lines become thinner due to the buildup of the silicate byproducts 220, the conductance of those word lines may be reduced, and thus may interfere with the operation of the memory array.

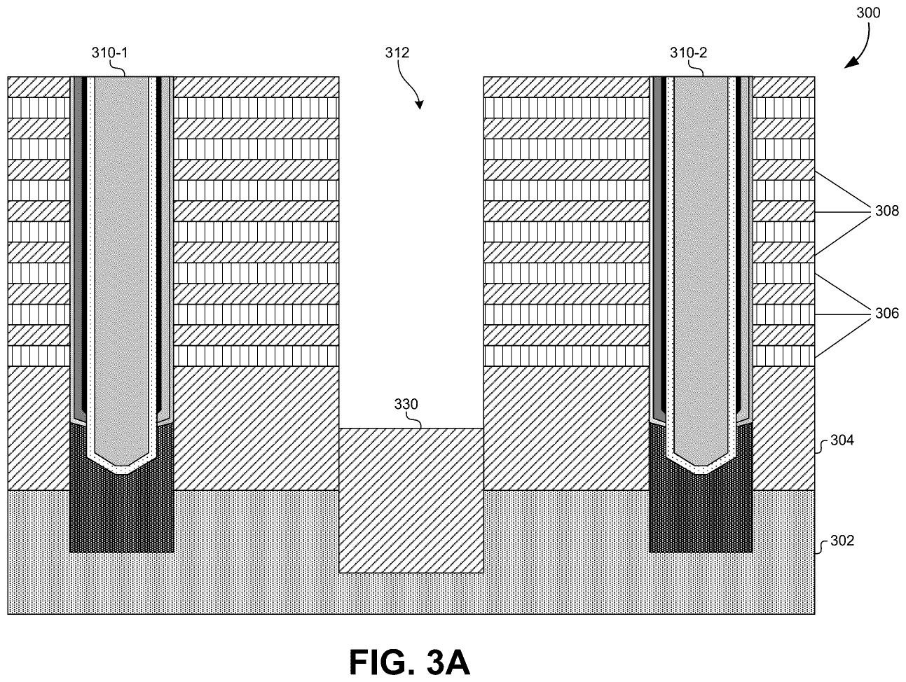

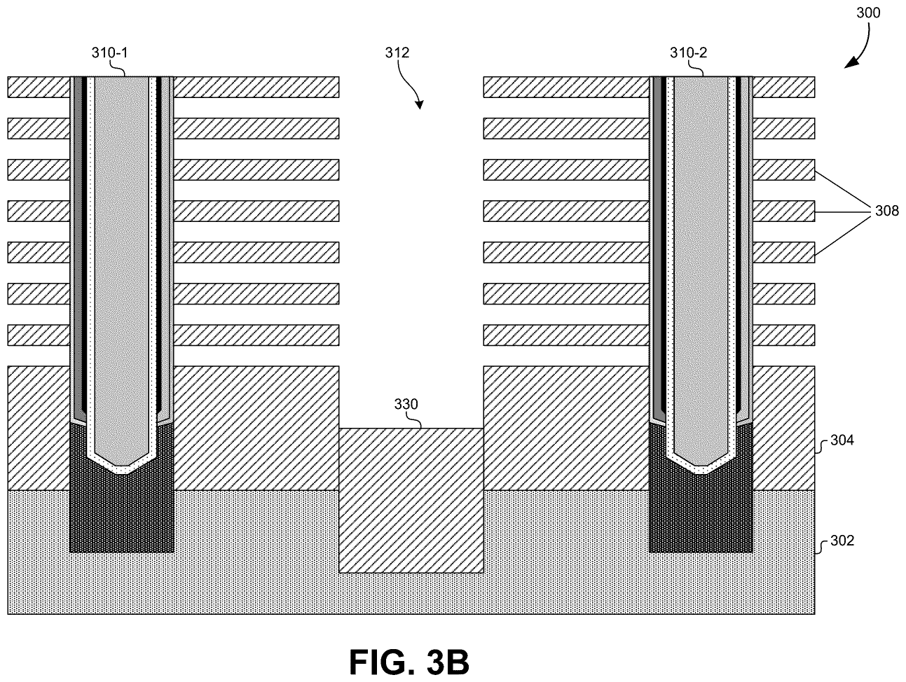

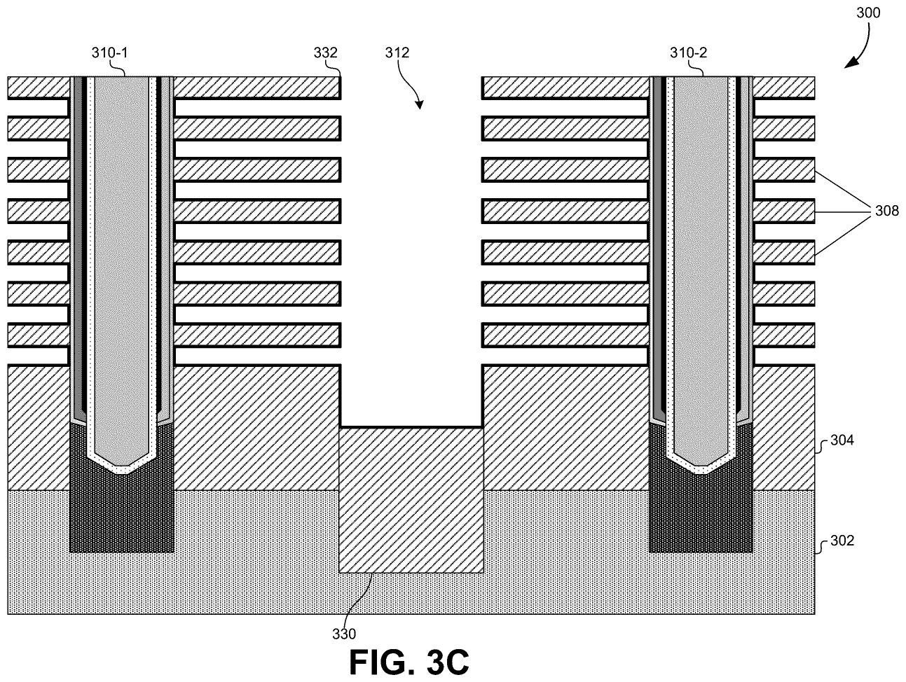

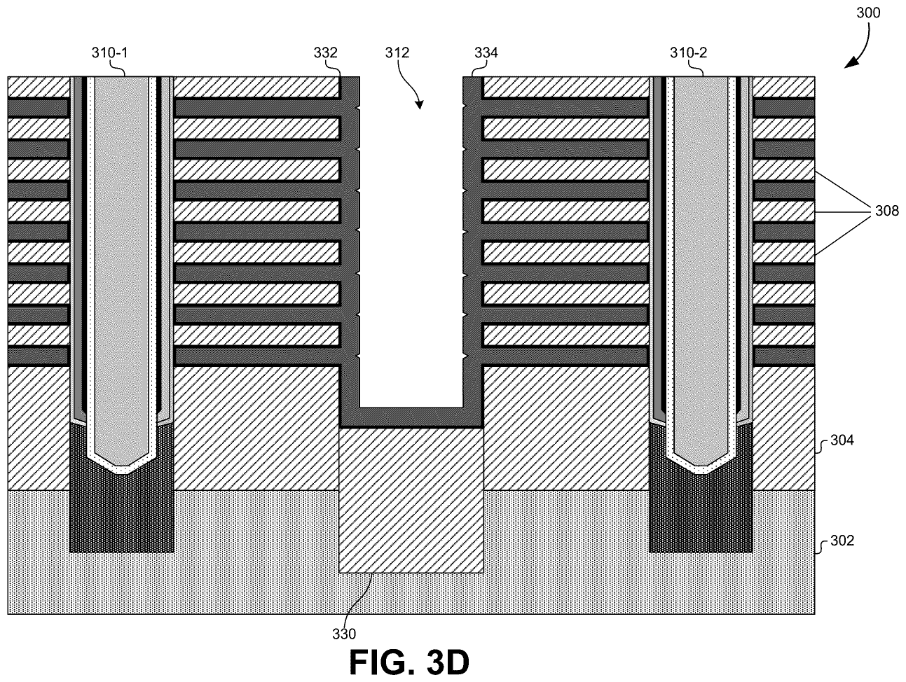

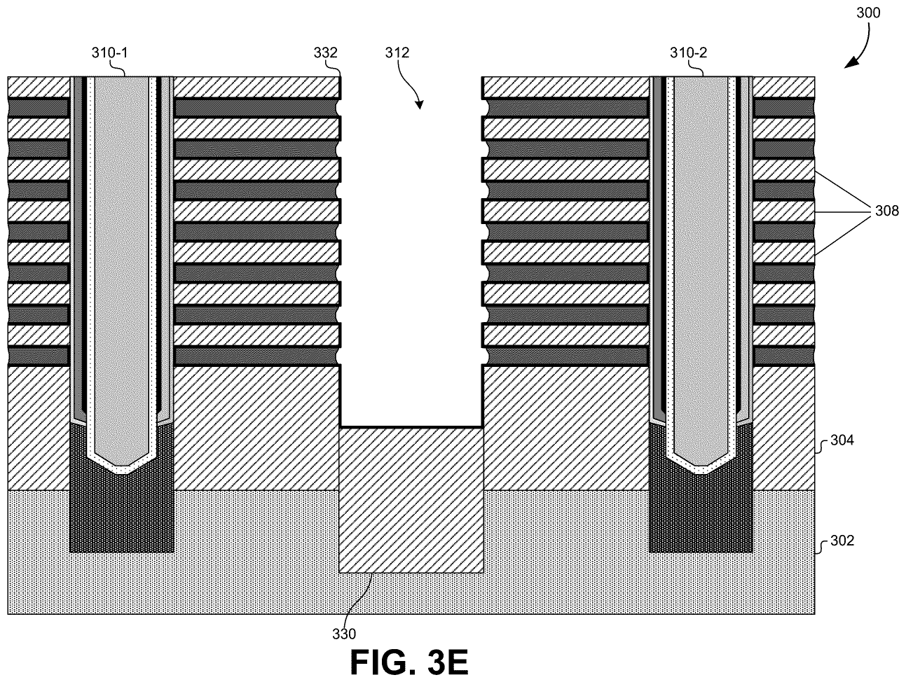

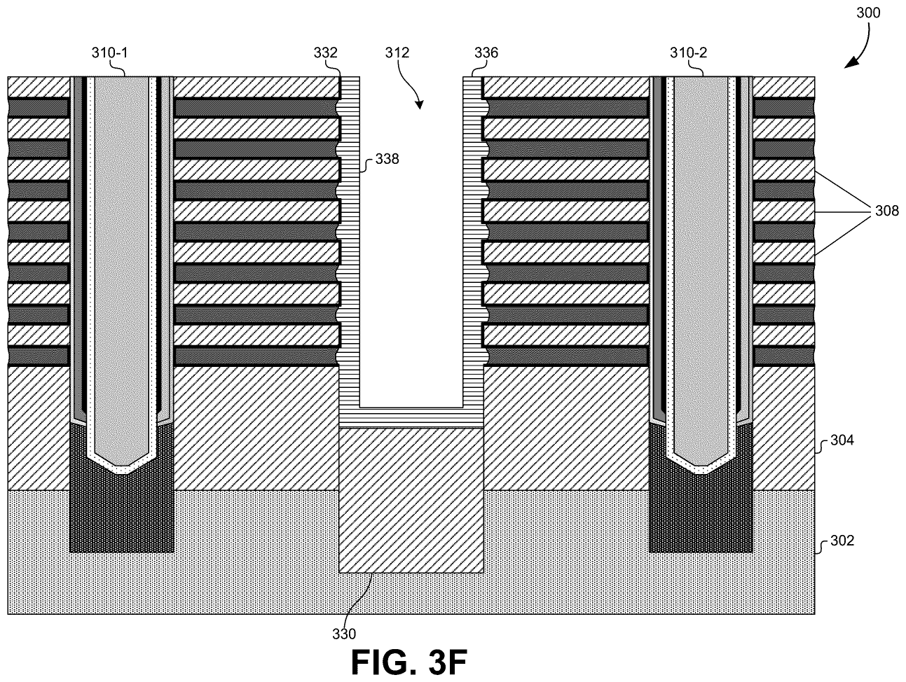

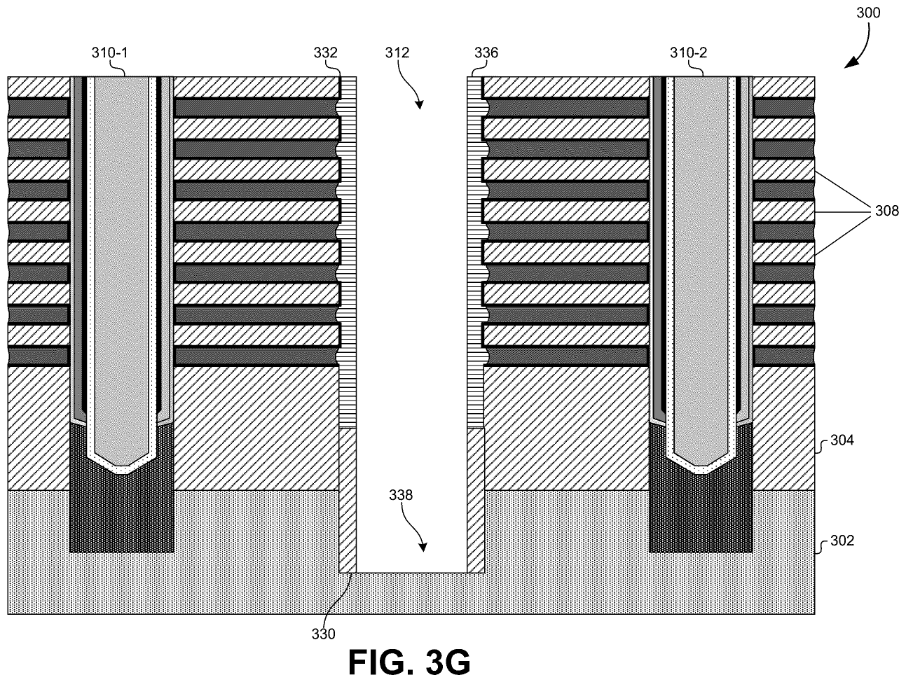

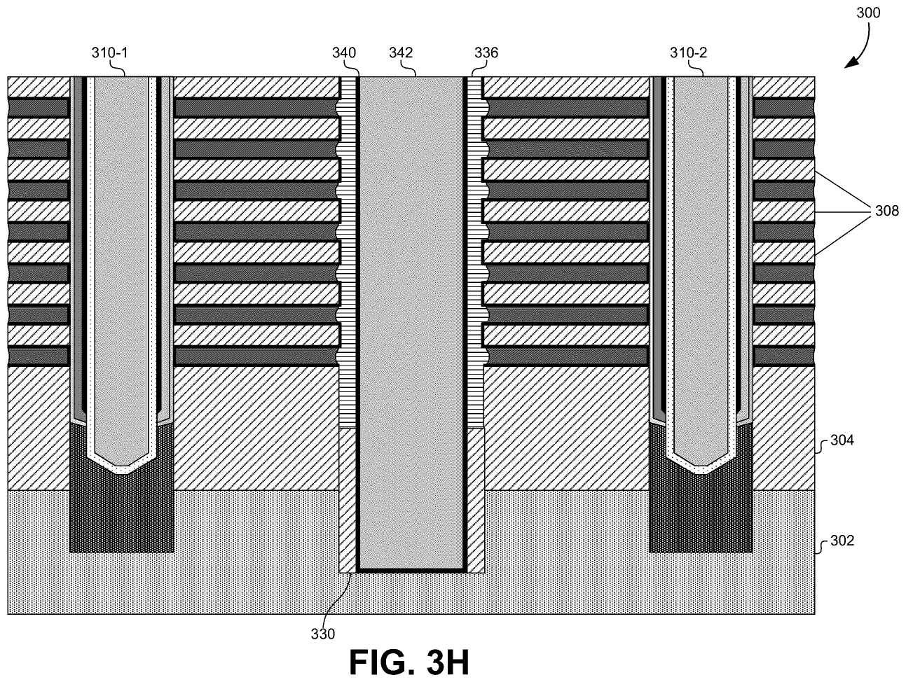

FIGS. 3A-3H illustrate process steps for forming a 3D NAND memory structure 300 using a protective insulating layer 330 and a dry etch process for exhuming the nitride layers, according to some embodiments. These figures may continue the process of fabricating the memory structure 300 from the stage illustrated in FIG. 2A. FIG. 3A illustrates an insulating layer 330 that may be formed to protect the silicon substrate 302, according to some embodiments. In order to overcome the problems associated with the wet etch process described above, a dry etch process may be used instead. Prior to this disclosure, dry etch processes were not used to remove the nitride layers 306 because the dry etch process would also remove a portion of the silicon in the silicon substrate 302. Specifically, while the dry etch process could be very selective in etching away the nitride layers 306 and leaving the oxide layers 308 and the first material layer 304, the dry etch process would also remove a significant amount of silicon from the silicon substrate 302. Wet etch processes were better suited for specifically targeting the nitride layers 306 without damaging the silicon substrate 302.

The embodiments described herein allow for the use of a dry etch process by depositing an insulating layer 330 at the bottom of the slit 312 to protect the silicon substrate 302 during the dry etch process. The material of the insulating layer 330 may include any dielectric, nonconducting, oxide material, such as silicon dioxide. As multiple insulating layers may be used throughout the fabrication process, the insulating layer 330 may also be referred to herein as a first insulating layer 330 to distinguish it from other insulating layers that may be applied in later fabrication steps.

The insulating layer 330 may be deposited at the bottom of the slit 312 using a directional deposition process. Specifically, a deposition process may be used to directionally deposit silicon on the bottom of the slit 312 and convert that silicon into silicon dioxide, repeating the steps until the insulating layer 330 has a sufficient thickness. This directional deposition process is configured to only deposit the silicon dioxide at the bottom of the slit 312 without coating the sides of the slit 312 with the insulating material. Specifically, the nitride layers 306 and the oxide layers 308 may remain exposed after the insulating layer 330 has been fully deposited. This allows a dry etch process to still have access to the nitride layers 306 after the insulating layer 330 has been deposited to protect the silicon substrate 302. Thus, the dry etch process may be used to effectively remove the nitride layers 306 without damaging the silicon substrate 302.

The insulating layer 330 may be deposited such that the height of the insulating layer 330 is above the top of the silicon substrate 302. Therefore, when the slit 312 is etched to a depth that penetrates below the top of the silicon substrate 302, the insulating layer 330 may begin below the top of the silicon substrate 302 and extend upwards with a thickness that is above the top of the silicon substrate 302. For example, the insulating layer 330 may be deposited to a thickness that is around a midpoint of the thickness of the first material layer 304. Recall that the thickness of the first material layer 304 may be greater than the thicknesses of the other nitride layers 306 and oxide layers 308. This increased thickness may allow the height of the insulating layer 330 to fall within the middle of the first material layer 304 with a margin for error. (It would be much more difficult if the first material layer 304 were the same thickness as the other nitride layers 308.) Depositing the insulating layer 330 to a thickness such that the top of the insulating layer 330 is within the range of the first material layer 304 ensures that none of the nitride layers 306 are blocked during the dry etch process, while also ensuring that the silicon substrate 302 is fully covered by the insulating layer 330.

FIG. 3B illustrates the 3D NAND memory structure 300 after the dry etch process is complete, according to some embodiments. As with the wet etch process described above, the dry etch process may leave recesses where the nitride layers 306 have been removed. These recesses may later be filled with a conductive material to form the word lines in the memory array. In contrast to the recesses illustrated in FIG. 2C however, the recesses illustrated in FIG. 3B are free of silicate deposits that tend to pinch off the recesses. Specifically, the recesses left behind from the dry etch process have sharper corners left behind by the oxide layers 308, and have a more uniform thickness throughout the horizontal length of the recesses. This provides a uniform conductivity and geometry for the conductive material that will later be deposited.

Various dry etch processes may be used, depending on the embodiment. Some implementations may use a gaseous mixture that is applied to the processing chamber that reacts with the nitride layers 306 through multiple steps to remove the nitride layers. For example, a first gas may be applied to bond with the nitride layers and form an outer layer of material, and a second gas may then be applied to remove that outer layer. This process may be repeated to incrementally remove the nitride layers 306. These gaseous mixtures may be very selective, such that they effectively remove silicon nitride without removing virtually any of the silicon oxide. For example, some dry etch processes may use a mixture of NF₃ gas and O₂ gas. Other dry etch processes may use a mixture of NF₃ gas and H₂ gas. Other dry etch processes may use a mixture of ClF₃ gas and H₂ gas.

FIG. 3C illustrates the application of a liner material to the recesses left by the dry etch process, according to some embodiments. The next step in the integration process flow for fabricating the 3D NAND memory structure 300 may include applying various thin layers to the recesses and exposed surfaces of the slit 312 before depositing the conductive material. For example, some embodiments may grow a thin layer of oxide on the silicon oxide 308 fins after the dry etch. Some embodiments may then add a liner, such as a TiN liner on top of the oxide layer. As depicted in FIG. 3C, these layers 332 may be used to coat the silicon oxide surfaces before applying the conductive material.

FIG. 3D illustrates the application of a conductive material to the recesses left behind by the dry etch process, according to some embodiments. In order to form the conductive word lines, a conductive material 334 may be formed on the exposed surfaces of the slit 312 and in the recesses left behind between the oxide layers 308. For example, some embodiments may use a tungsten (W) fill to grow a solid word line between the oxide layers 308. Other conductive or metal materials may be used besides tungsten. Note that the deposition process for forming the conductive material 334 may fill the recesses between the oxide layers 308, as well as forming a layer of the conductive material 334 that surrounds an interior of the slit 312. The conductive material 334 may also form a layer on the exposed top surface of the first insulating material 330 at the bottom of the slit 312.

FIG. 3E illustrates a separation process for removing a portion of the conductive material 334, according to some embodiments. In order to electrically isolate the individual word lines from each other, the conductive material 334 that coats the interior of the slit 312 may be removed using, for example, a tungsten separation process that etches away the coating of conductive material 334. Note that this removal process may extend somewhat into the recesses, but not far enough to damage the conductive word lines between the oxide layers 308. This removal process may also remove the conductive material 334 that was formed on the first material layer 304 and/or the top of the first insulating layer 302.

FIG. 3F illustrates the application of a second insulating layer 338 to the slit 312, according to some embodiments. This step may be referred to as an oxide fill step that deposits a layer of oxide as the second insulating layer 338. The second insulating layer 338 may coat the sides that surround the interior of the slit 312. The second insulating layer 338 may also coat the exposed top portion of the first insulating layer 330. Any type of oxide may be used for the second insulating layer 338. The second insulating layer may serve to electrically isolate the different word lines between the oxide layers 308.

FIG. 3G illustrates a directional etch that may be used to again expose the silicon substrate 302, according to some embodiments. Some implementations of the 3D NAND memory structure 300 may benefit from having the slit material contact the silicon substrate 302. For example, filling the slit 312 with material that extends down into the silicon substrate 302 may result in a more rigid and supportive structure for the memory array. However, the first insulating material 330 previously formed to protect the silicon substrate 302 now blocks the access to the silicon substrate 302. Therefore, a “bottom-punch” etch that provides a directional etch straight down into the slit 312 may be used to remove the bottom of the second insulating layer 336 and the bulk of the first insulating layer 330. For example, a reactive-ion etch (ME) process may be used to directionally etch the first insulating layer 330 and the second insulating layer 336 at the bottom 338 of the slit 312 as illustrated in FIG. 3G. In some implementations, the ME process may etch down to the bottom of the first insulating layer 330 to just expose the silicon substrate 302. In other implementations, the REI process may continue to etch further down into the silicon substrate 302 below a bottom surface of the first insulating layer 330.

The resulting stack may leave the first insulating layer 330 coating the sides of a bottom portion of the slit 312 as depicted in FIG. 3G. Additionally, the second insulating layer 336 may coat sides of a top portion of the slit 312 as depicted in FIG. 3G. Note that other materials may also coat portions of the sides or sidewalls of the slit 312 without restriction.

FIG. 3H illustrates a solid fill material 342 and a liner in the finished slit 312, according to some embodiments. After etching down to the silicon substrate 302, a liner 340, such as a TiN liner may be applied to the interior of the slit 312. The liner 340 may coat the sides of the slit 312 to cover the first insulating material 330 and/or the second insulating material 336. The liner 340 may also coat the bottom 338 of the slit 312 to cover the exposed portion of the silicon substrate 302. Next, a solid fill material 342 may be formed inside the slit 312. For example, some embodiments may use polysilicon as the solid fill material 342. Other embodiments may use tungsten or other metals as a solid fill material.

FIG. 3H illustrates a final structure comprised of the silicon substrate 302, the plurality of alternating material layers (now formed from alternating layers of silicon dioxide and tungsten), and a slit. The first insulating layer 330 may coat the sides of the bottom portion of the slit, and the second insulating layer may coat the sides of the top portion of the slit. The solid fill material may extend from the top of the stack of alternating material layers down into the silicon substrate 302.

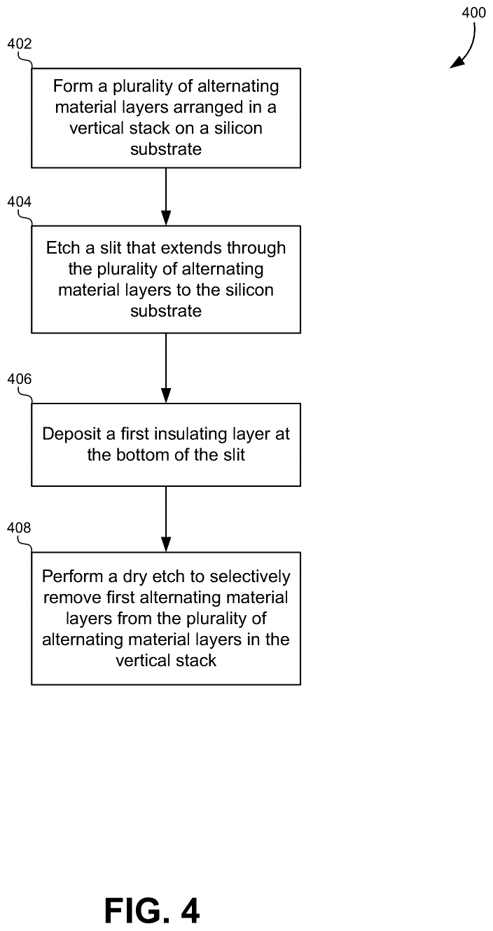

FIG. 4 illustrates a flowchart 400 of a method for fabricating a 3D NAND memory structure, according to some embodiments. Each of the operations described below may be carried out by a semiconductor processing system as described above in FIG. 1. The semiconductor processing system may include a plurality of processing chambers configured to perform the etch, deposition, and/or other processes described below. In some implementations, these operations may be embodied in one or more sets of instructions stored on one or more memory devices that may be executed by one or more processors in one or more controllers that cause the processing chambers to perform these operations. For example, the instructions may be stored collectively on a central controller or on distributed controllers for each processing chamber.

The method may include forming a plurality of alternating material layers arranged in a vertical stack on a silicon substrate (402). The alternating material layers may be formed as described above in FIG. 2A, and may include alternating material layers of nitride and oxide materials, such as silicon nitride and/or silicon dioxide. A first material layer positioned adjacent to or on top of the silicon substrate may be substantially thicker than the similar material layers throughout the rest of the stack.

The method may also include etching a slit that extends through the plurality of alternating material layers to the silicon substrate (404). For example, a hard mask may be patterned on top of the alternating material layers to etch a slit that extends through material layers down to the silicon substrate as described above in FIG. 2A. The slit may extended down to a surface or top of the silicon substrate, or may alternatively extend below the top of the silicon substrate into the silicon substrate itself.

The method may further include depositing a first insulating layer at the bottom of the slit (406). As illustrated above in FIG. 3A, the first insulating layer may cover the exposed surface of the silicon substrate. The top of the first insulating layer may be below the first nitride layer in the alternating layers of material in the stack. For example, the top of the first insulating layer may be positioned within the first material layer of oxide above the silicon substrate. The first insulating layer may be directionally deposited on the bottom of the slit much that the material of the first insulating layer does not coat the internal sides of the slit, thereby leaving the alternating layers (e.g., the nitride layers to be removed) exposed. The first insulating layer may be composed of a dielectric or oxide material, such as silicon dioxide.

The method may also include performing a dry etch to selectively remove first alternating material layers from the plurality of alternating material layers in the vertical stack (408). The dry etch may be configured to selectively remove the first alternating material layers, such as the nitride layers without removing second material layers, such as the oxide layers. In some cases, the dry etch may also be configured to selectively remove the silicon substrate, were the silicon substrate not protected by the first insulating layer. Therefore, the first insulating layer may protect the silicon substrate during the dry etch process by covering the exposed areas of the silicon substrate, and the dry etch process may be configured to not selectively remove the first insulating layer. The dry etch may be performed as an iterative two-gas process, using gases such as NF3 and O2, NF3 and H2, ClF3 and H2, and/or other similar combinations.

It should be appreciated that the specific steps illustrated in FIG. 4 provide particular methods of fabricating a three-dimensional (3D) NAND memory structure according to various embodiments. Other sequences of steps may also be performed according to alternative embodiments. For example, alternative embodiments may perform the steps outlined above in a different order. Moreover, the individual steps illustrated in FIG. 4 may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A three-dimensional (3D) NAND memory structure comprising:
a silicon substrate;
a plurality of alternating material layers arranged in a vertical stack on the silicon substrate, wherein a slit extends through the plurality of alternating material layers to the silicon substrate to divide a plurality of channel holes into a memory array, wherein the slit is perpendicular to the plurality of alternating material layers; and
a first insulating layer deposited at the bottom of the slit, wherein the first insulating layer comprises a material that protects the silicon substrate during a dry etch process that selectively removes first alternating material layers from the plurality of alternating material layers.

2. The 3D NAND memory structure of claim 1, wherein the alternating material layers comprise alternating layers of an oxide material and a nitride material.

3. The 3D NAND memory structure of claim 1, wherein a first material layer in the plurality of alternating material layers that is adjacent to the silicon substrate is thicker than the remaining material layers in the plurality of alternating material layers.

4. The 3D NAND memory structure of claim 1, wherein the slit extends to a surface of the silicon substrate without penetrating the surface of the silicon substrate.

5. The 3D NAND memory structure of claim 1, wherein the slit extends below a surface of the silicon substrate.

6. The 3D NAND memory structure of claim 1, wherein the first insulating layer extends below a surface of the silicon substrate.

7. The 3D NAND memory structure of claim 1, wherein a top of the first insulating layer is between a surface of the silicon substrate and a top of a first material layer in the plurality of alternating material layers that is adjacent to the silicon substrate.

8. The 3D NAND memory structure of claim 7, wherein the first insulating layer does not coat sides of the slit above the top of the first insulating layer.

9. A three-dimensional (3D) NAND memory structure comprising:
a silicon substrate;
a plurality of alternating material layers arranged in a vertical stack on the silicon substrate, wherein a slit extends through the plurality of alternating material layers to the silicon substrate to divide a plurality of channel holes in a memory array, wherein the slit is perpendicular to the plurality of alternating material layers;
a first insulating layer coating sides of a bottom portion of the slit; and
a second insulating layer coating sides of a top portion of the slit.

10. The 3D NAND memory structure of claim 9, wherein the alternating material layers comprise alternating layers of an oxide material and a metal, wherein the metal forms a gate electrode for individual memory cells in the memory structure.

11. The 3D NAND memory structure of claim 9, wherein the first insulating layer comprises a silicon oxide material.

12. The 3D NAND memory structure of claim 9, wherein a top of the first insulating layer is between a surface of the silicon substrate and a top of a first material layer in the plurality of alternating material layers that is adjacent to the silicon substrate.

13. The 3D NAND memory structure of claim 9, further comprising a solid fill material inside the first insulating layer and the second insulating layer.

14. A method of fabricating a three-dimensional (3D) NAND memory structure, the method comprising:
forming a plurality of alternating material layers arranged in a vertical stack on a silicon substrate;
etching a slit that extends through the plurality of alternating material layers to the silicon substrate;
depositing a first insulating layer at the bottom of the slit; and
performing a dry etch to selectively remove first alternating material layers from the plurality of alternating material layers in the vertical stack, wherein the first insulating layer comprises a material that protects the silicon substrate during the dry etch process.

15. The method of claim 14, wherein the dry etch process uses gases that would also selectively remove a portion of the silicon substrate if not protected by the first insulating layer.

16. The method of claim 14, wherein the gases comprise:
NF₃ and O₂;
NF₃ and H₂; or
ClF₃ and H₂.

17. The method of claim 14, further comprising filling recesses left after removing the first alternating material layers with a conductive material to form word lines for the memory structure.

18. The method of claim 14, further comprising depositing a second insulating layer on top of the first insulating layer such that the second insulating layer coats a top of the first insulating layer and coats sides of the slit.

19. The method of claim 18, further comprising etching a hole through the second insulating layer that coats the top of the first insulating layer and the second insulating layer to expose the silicon substrate using a directional etch to leave the second insulating layer that coats the sides of the slit.

20. The method of claim 19, further comprising filling the hole with a solid fill material.
